(19) United States
(12) Patent Application Publication
(10) Pub. No.: US 2024/0290616 A1
(43) Pub. Date: Aug. 29, 2024

(54) SILICON CARBIDE SEMICONDUCTOR DEVICE AND MANUFACTURING METHOD OF THE SAME

(71) Applicants: DENSO CORPORATION, Kariya-city (JP); FUJI ELECTRIC CO., LTD., Kawasaki-shi (JP)

(72) Inventors: Tomohiro MIMURA, Kariya-city (JP); Kensuke HATA, Kariya-city (JP); Masanobu IWAYA, Matsumoto-shi (JP)

(21) Appl. No.: 18/435,035

(22) Filed: Feb. 7, 2024

(30) Foreign Application Priority Data
Feb. 28, 2023 (JP) 2023-030215

(51) Int. Cl. H01L 21/04; H01L 23/34; H01L 29/06; H01L 29/16; H01L 29/34; H01L 29/66; H01L 29/78

(52) U.S. Cl. CPC H01L 21/045; H01L 21/046; H01L 23/34; H01L 29/0623; H01L 29/1608; H01L 29/34; H01L 29/66068; H01L 29/7811; H01L 29/7813

(57) ABSTRACT

A silicon carbide semiconductor device has a semiconductor substrate, a trench gate structure disposed in the semiconductor substrate, a first electrode electrically connected to an impurity region and a bae layer of the semiconductor substrate, a second electrode connected to a substrate, and an interlayer insulating film disposed between a gate electrode and the first electrode. The trench gate structure includes a gate insulating film disposed in a trench of the semiconductor substrate and the gate electrode disposed on the gate insulating film. A portion of the semiconductor substrate adjoining the trench has a termination structure in which dangling bonds are terminated with at least one of nitrogen, hydrogen or phosphorous. The interlayer insulating film has a contact insulating film that is in contact with the gate electrode. The contact insulating film is provided by a deposited film.

### CROSS REFERENCE TO RELATED APPLICATION

The present application claims the benefit of priority from Japanese Patent Application No. 2023-030215 filed on Feb. 28, 2023. The entire disclosures of the above application are incorporated herein by reference.

### TECHNICAL FIELD

The present disclosure relates to a silicon carbide (SiC) semiconductor device having a trench gate structure and made of silicon carbide (SiC), and a manufacturing method of the same.

### BACKGROUND

Conventionally, a SiC semiconductor device having a trench gate structure and made of SiC has been proposed. For example, the SiC semiconductor device is formed with a metal oxide semiconductor field effect transistor (MOSFET) having a trench gate structure.

### SUMMARY

The present disclosure describes a SiC semiconductor device having a semiconductor substrate made of silicon carbide, a trench gate structure disposed in the semiconductor substrate, a first electrode electrically connected to an impurity region and a bae layer of the semiconductor substrate, a second electrode connected to the semiconductor substrate, and an interlayer insulating film disposed between a gate electrode of the trench gate structure and the first electrode. The present disclosure also describes a manufacturing method of the SiC semiconductor device.

### BRIEF DESCRIPTION OF THE DRAWINGS

Objects, features, and advantages of the present disclosure will become more apparent from the following detailed description made with reference to the accompanying drawings, in which:

FIG. 1 is a cross-sectional view of a SiC semiconductor device according to a first embodiment;

FIG. 2A is a cross-sectional view for showing a manufacturing process of the SiC semiconductor device shown in FIG. 1;

FIG. 2B is a cross-sectional view for showing the manufacturing process of the SiC semiconductor device subsequent to FIG. 2A;

FIG. 2C is a cross-sectional view for showing the manufacturing process of the SiC semiconductor device subsequent to FIG. 2B;

FIG. 2D is a cross-sectional view for showing the manufacturing process of the SiC semiconductor device subsequent to FIG. 2C;

FIG. 2E is a cross-sectional view for showing the manufacturing process of the SiC semiconductor device subsequent to FIG. 2D;

FIG. 2F is a cross-sectional view for showing the manufacturing process of the SiC semiconductor device subsequent to FIG. 2E;

FIG. 3 is a cross-sectional view of a SiC semiconductor device according to a second embodiment;

FIG. 4A is a cross-sectional view for showing a manufacturing process of the SiC semiconductor device shown in FIG. 3;

FIG. 4B is a cross-sectional view for showing the manufacturing process of the SiC semiconductor device subsequent to FIG. 4A;

FIG. 4C is a cross-sectional view for showing the manufacturing process of the SiC semiconductor device subsequent to FIG. 4B; and

FIG. 4D is a cross-sectional view for showing the manufacturing process of the SiC semiconductor device subsequent to FIG. 4C.

### DETAILED DESCRIPTION

To begin with, a relevant technology will be described only for understanding the embodiments of the present disclosure.

A SiC semiconductor device having a trench gate structure and made of SiC has been proposed. Such a SiC semiconductor device is formed with a metal oxide semiconductor field effect transistor (MOSFET) having a trench gate structure. For example, the SiC semiconductor device includes an n-type substrate, an n-type drift layer disposed on the substrate, a p-type base layer disposed on the drift layer, and an n-type source region disposed in a surface layer portion of the base layer. In addition, the SiC semiconductor device has the trench gate structure that penetrates the source region and reaches the drift layer, a first electrode that is electrically connected to the base layer and the source region, and a second electrode that is connected to the substrate.

The trench gate structure of the SiC semiconductor device is composed of a gate insulating film and a gate electrode. The gate insulating film is formed on a wall surface of a trench that is formed to reach the drift layer. The gate electrode is formed of doped polysilicon and buried on the gate insulating film in the trench. An interlayer insulating film is disposed between the gate electrode and the first electrode for insulating the gate electrode and the first electrode from each other. In such a SiC semiconductor device, it has been proposed to form the interlayer insulating film by thermally oxidizing a portion of the doped polysilicon forming the gate electrode, the portion being located adjacent to the opening of the trench.

In such a SiC semiconductor device, when a voltage equal to or higher than a threshold voltage is applied to the gate electrode, an inversion layer is formed in a portion of the base layer that is in contact with the trench. Thus, the SiC semiconductor device is turned to an ON state in which an electric current is caused between the first electrode and the second electrode through the inversion layer.

In such a SiC semiconductor device, it is conceivable to employ a termination structure in which dangling bonds of the base layer at the interface with the gate insulating film are terminated by a predetermined atom of such as nitrogen, hydrogen, or phosphorus in order to lower the interface state. In such a case, if the interlayer insulating film is formed by thermally oxidizing the doped polysilicon forming the gate electrode as described above, the atom such as nitrogen in the termination structure may be replaced with oxygen, resulting in variation in threshold voltage.

The present disclosure provides a SiC semiconductor device which is capable of suppressing variation in threshold voltage and a method for manufacturing the SiC semiconductor device.

According to a first aspect of the present disclosure, a SiC semiconductor device includes a semiconductor substrate, a trench gate structure, a first electrode, a second electrode, and an interlayer insulating film. The semiconductor substrate includes: a substrate of a first or second conductivity type made of SiC; a drift layer of the first conductivity type disposed on the substrate and having an impurity concentration lower than that of the substrate; a base layer of the second conductivity type disposed on the drift layer; and an impurity region of the first conductivity type disposed in a surface layer portion of the base layer. The trench gate structure includes a gate insulating film disposed on a wall surface of a trench that penetrates the impurity region and the base layer and reaches the drift layer, and a gate electrode disposed on the gate insulating film. The first electrode is electrically connected to the impurity region and the base layer. The second electrode is electrically connected to the substrate. The interlayer insulating film is disposed between the gate electrode and the first electrode to insulate the gate electrode and the first electrode from each other. Further, a portion of the semiconductor substrate adjoining the trench has a termination structure in which dangling bonds are terminated with at least one selected from a group consisting of nitrogen, hydrogen, and phosphorus. The interlayer insulating film includes a contact insulating film that is in contact with the gate electrode. The contact insulating film is provided by a deposited film.

In such a configuration, since the contact insulating film is provided by the deposited film, the atom such as nitrogen bonded to the dangling bonds in the termination structure is less likely to be replaced with oxygen, as compared with a case where the contact insulating film is provided by an oxidized film or the like. Accordingly, it is possible to suppress the occurrence of variation in the threshold voltage.

According to a second aspect of the present disclosure, a manufacturing method of the SiC semiconductor device according to the first aspect described above includes: preparing the semiconductor substrate formed with the base layer, the impurity region, and the trench; arranging the gate insulating film on the wall surface of the trench; forming the termination structure by bonding the at least one selected from the group consisting of nitrogen, hydrogen, and phosphorus to the dangling bonds in the portion of the semiconductor substrate adjoining the trench; arranging the gate electrode on the gate insulating film; arranging the interlayer insulating film in a region including a portion above the gate electrode; and patterning the interlayer insulating film so as to expose the impurity region and the base layer. The arranging of the interlayer insulating film includes arranging a contact insulating film by a deposition method.

In such a method, since the contact insulating film is arranged by the deposition method, the atom such as nitrogen in the termination structure is less likely to be replaced with oxygen as compared with a case where the contact insulating film is composed of an oxidized film or the like. As such, it is possible to manufacture a SiC semiconductor device in which the occurrence of variation in threshold voltage is suppressed.

Hereinafter, embodiments of the present disclosure will be described with reference to the drawings. In the following embodiments, the same or equivalent parts are denoted by the same reference numerals.

### First Embodiment

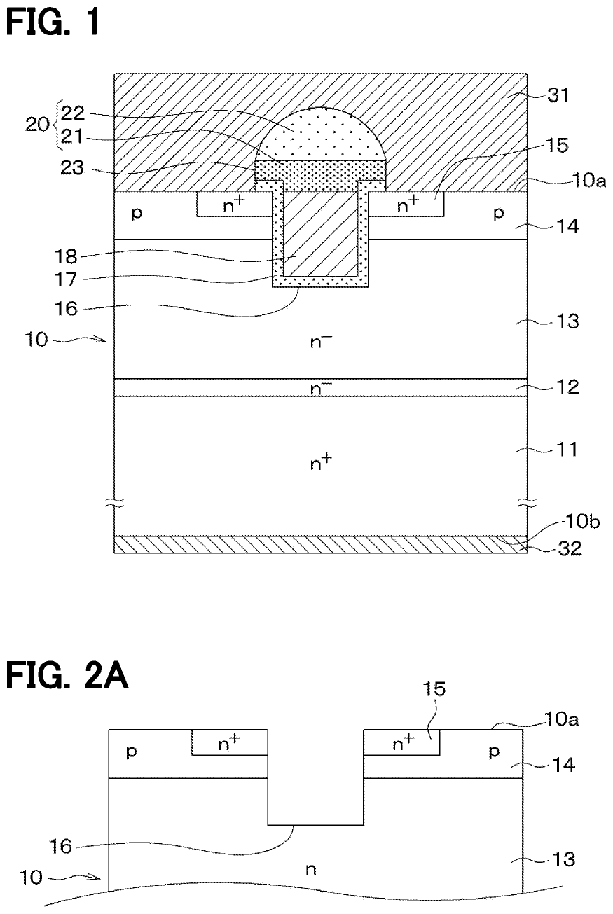

A SiC semiconductor device of a first embodiment will be described with reference to FIG. 1. In the present embodiment, a SiC semiconductor device provided with a metal oxide semiconductor field effect transistor (MOSFET) as a semiconductor element will be described as an example. Although not particularly illustrated here, the SiC semiconductor device includes an element section, an outer peripheral section disposed around the element section, and the like. The MOSFET shown in FIG. 1 is formed in the element section of the SiC semiconductor device.

In the present embodiment, the SiC semiconductor device is configured by using a semiconductor substrate 10. The semiconductor substrate 10 includes an n⁺-type substrate 11 made of SiC, an n⁻-type buffer layer 12 disposed on the substrate 11, and an n⁻-type drift layer 13 disposed on the buffer layer 12. Also, the semiconductor substrate 10 includes a p-type base layer 14 disposed on the drift layer 13 and an n⁺-type source region 15 disposed in a surface layer portion of the base layer 14. Hereinafter, a surface of the semiconductor substrate 10 adjacent to the base layer 14 will be referred to as a first surface 10a of the semiconductor substrate 10, and a surface of the semiconductor substrate 10 adjacent to the substrate 11 will be referred to as a second surface 10b of the semiconductor substrate 10. The first surface 10a and the second surface 10b are opposite to each other. In the present embodiment, the source region 15 corresponds to an impurity region.

As the substrate 11, for example, a substrate having a specific resistance of 30 mΩ·cm or less (for example, 20 mΩ·cm), and having a front surface of a (0001) Si plane and an off angle of 0.5 to 5° with respect to the (0001) Si plane is used. The substrate 11 has an n-type impurity concentration of, for example, 5.0×10¹⁸ to 1.0×10²⁰ cm⁻³. Note that the substrate 11 of the present embodiment constitutes a drain layer of the MOSFET.

The buffer layer 12 has an n-type impurity concentration of, for example, 1.0×10¹⁸ to 1×10¹⁹ cm⁻³. The drift layer 13 has an n-type impurity concentration of, for example, 1.0×10¹⁵ to 5.0×10¹⁶ cm⁻³.

The base layer 14 provides a part that forms a channel region. For example, the base layer 14 has a p-type impurity concentration of about 3.0×10¹⁷ cm⁻³ and a thickness of 0.5 to 2 μm. The source region 15 has an impurity concentration higher than that of the drift layer 13. For example, the source region 15 has the n-type impurity concentration of about 2.5×10¹⁸ to 1.0×10¹⁹ cm⁻³ in a surface layer portion, and the thickness of 0.5 to 2 μm. Note that the film thicknesses and the like of the drift layer 13, the base layer 14, and the source region 15 are arbitrary and are not limited to the examples described above.

A trench 16 is formed in the semiconductor substrate 10 so as to penetrate the base layer 14 and the source region 15 from the first surface 10a side and reach the drift layer 13. The base layer 14 and the source region 15 are disposed so as to adjoin the trench 16 in a lateral direction. Although only one trench 16 is illustrated in FIG. 1, multiple trenches 16 are actually arranged at equal intervals in the lateral direction, that is, in a left and right direction of FIG. 1 into a stripe shape.

A gate insulating film 17 is disposed on a wall surface of the trench 16. A gate electrode 18 is disposed on the surface of the gate insulating film 17. The gate electrode 18 is made of doped polysilicon. In the present embodiment, the trench gate structure is configured in this manner. Note that the gate insulating film 17 is arranged on the wall surface of the trench 16 and extends onto the first surface 10a of the semiconductor substrate 10. That is, the gate insulating film 17 is disposed on the wall surface of the trench 16 and on a portion of the first surface 10a of the semiconductor substrate 10, the portion being on a periphery of the opening of the trench 16. In this case, the gate insulating film 17 on the first surface 10a of the semiconductor substrate 10 is formed so as to expose the base layer 14 and the source region 15.

As will be described later, the gate insulating film 17 of the present embodiment is formed by a chemical vapor deposition (CVD) method or a physical vapor deposition (PVD) method. In other words, in the present embodiment, the gate insulating film 17 is provided by a deposited film. Therefore, the thickness of a portion of the gate insulating film 17 being in contact with the source region 15 is 1.3 times or less the thickness of a portion of the gate insulating film 17 being in contact with the base layer 14.

Although not shown in detail, dangling bonds of the semiconductor substrate 10 at the interface with the gate insulating film 17 (that is, the trench 16) are bonded with a predetermined impurity in order to lower the interface state. That is, the semiconductor substrate 10 has a termination structure in which the dangling bonds at the interface with the gate insulating film 17 are terminated with the predetermined impurity. Examples of the predetermined impurity include nitrogen, hydrogen, and phosphorus. In the present embodiment, the dangling bonds are terminated with nitrogen.

An interlayer insulating film 20 is disposed on the gate electrode 18 so as to cover the opening of the trench 16 and to insulate the gate electrode 18 from an upper electrode 31, which will be described later. The interlayer insulating film 20 of the present embodiment includes a lower insulating film 21 that is in contact with the gate electrode 18 and an upper insulating film 22 that is disposed on the lower insulating film 21. The lower insulating film 21 is provided by a deposited film that is formed by a CVD method, a PVD method, or the like. For example, the lower insulating film 21 is provided by an oxide film (e.g., SiO₂), a nitride film (SiN), non-doped polysilicon, or the like. In the present embodiment, the CVD method and the PVD method correspond to a deposition method. The upper insulating film 22 is formed of borophospho silicate glass (BPSG) or the like.

Note that the lower insulating film 21 may be composed of one layer such as an oxide film. Alternatively, the lower insulating film 21 may be composed of two or more different types of insulating films stacked on top of another. In addition, since the lower insulating film 21 is provided by the deposited film, it is preferable that the thickness of the lower insulating film 21 is preferably 40 nm or more so that variation in thickness in the in-plane direction can be suppressed. The term “non-doped” of the non-doped polysilicon as used herein means a state in which the amount of impurities is small enough to insulate the gate electrode 18 from the upper electrode 31, which will be described later, and does not exclude the presence of impurities of an error degree that may be included in the manufacturing process. In the present embodiment, the lower insulating film 21 corresponds to a contact insulating film.

The interlayer insulating film 20 of the present embodiment is disposed above the gate insulating film 17 formed around the opening of the trench 16 on the first surface 10a of the semiconductor substrate 10 while covering the opening of the trench 16. In other words, the interlayer insulating film 20 has a shape protruding outward from the opening of the trench 16, when viewed in a direction normal to the first surface 10a of the semiconductor substrate 10 (hereinafter simply referred to as the normal direction), that is in a plan view along the normal direction. However, similar to the gate insulating film 17, the interlayer insulating film 20 is disposed so as to expose the base layer 14 and the source region 15. That is, a contact hole 23 is formed in the gate insulating film 17 and the interlayer insulating film 20 so as to expose the base layer 14 and the source region 15. The normal direction corresponds to a stacking direction of the drift layer 13 and the base layer 14. Thus, it can be said that the interlayer insulating film 20 has a shape protruding outward from the opening of the trench 16 when viewed in the stacking direction, or that the interlayer insulating film 20 has a shape protruding outward from the opening of the trench 16 in a planar direction of the semiconductor substrate 10 parallel to the first surface 10a. The shape when viewed in the normal direction or the stacking direction can be referred to as the planar shape.

The upper insulating film 22 of the present embodiment has a rounded surface in order to improve the embeddability of the upper electrode 31 described later.

The upper electrode 31 as a source electrode is disposed above the first surface 10a of the semiconductor substrate 10. The upper electrode 31 is insulated from the gate electrode 18 and is connected to the base layer 14 and the source region 15 through the contact hole 23. In the present embodiment, the upper electrode 31 is made of a plurality of metals such as Ni and Al. A portion of the plurality of metals that is in contact with a portion forming n-type SiC (i.e., the source region 15) is made of a metal capable of making an ohmic contact with the n-type SiC. In addition, at least a portion of the plurality of metals that is in contact with p-type SiC (i.e., the base layer 14) is made of a metal capable of making an ohmic contact with the p-type SiC. In the present embodiment, the upper electrode 31 corresponds to a first electrode.

A lower electrode 32 as a drain electrode is disposed adjacent to the second surface 10b of the semiconductor substrate 10. The lower electrode 32 is electrically connected to the substrate 11. In the present embodiment, the lower electrode 32 corresponds to a second electrode. In the present embodiment, with such a structure, MOSFET of an n-channel type inverted trench gate structure is formed. The element section is configured by arranging a plurality of such MOSFETs.

The SiC semiconductor device of the present embodiment have the configurations as described hereinabove. In such a SiC semiconductor device, when a gate voltage equal to or higher than a threshold voltage is applied to the gate electrode 18, the inversion layer is formed in the portion of the base layer 14 adjoining the trench 16, so the SiC semiconductor device is turned to the ON state in which a current is caused to flow between the upper electrode 31 and the lower electrode 32.

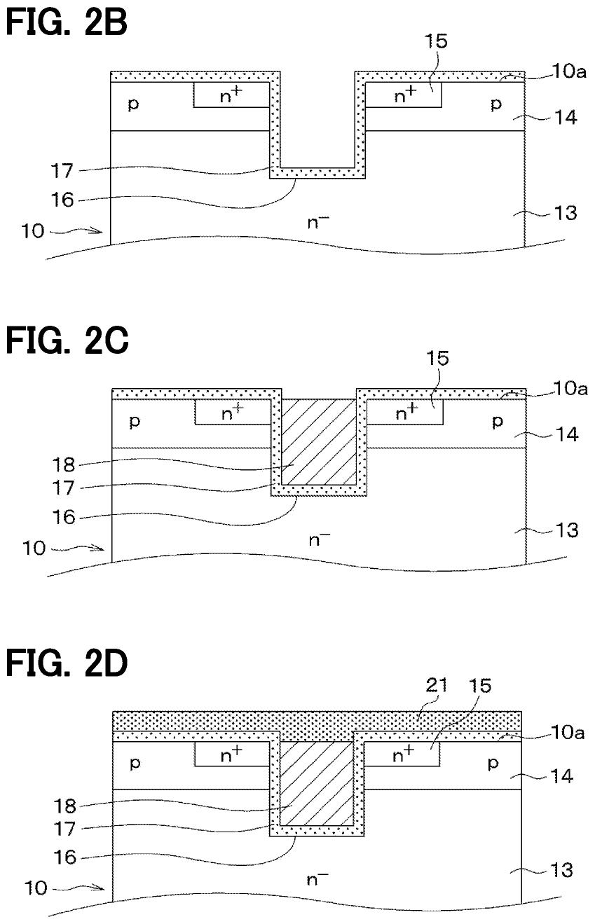

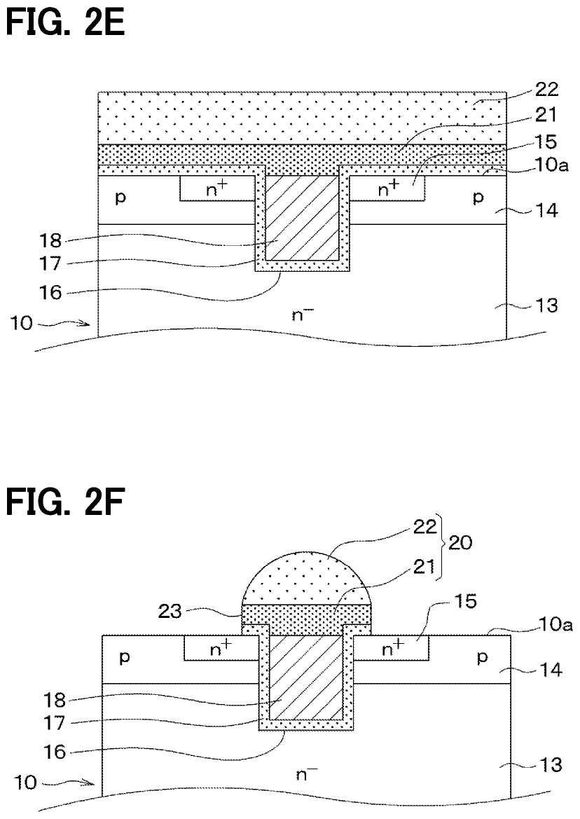

Next, a manufacturing method of the SiC semiconductor device will be described with reference to FIGS. 2A to 2F. In FIGS. 2A to 2F, illustrations of the buffer layer 12, the substrate 11, and the like on the second surface 10b side of the semiconductor substrate 10 are omitted.

First, as shown in FIG. 2A, a semiconductor substrate 10 in which a base layer 14, a source region 15 and the like are formed as well as a trench 16 is formed is prepared.

Subsequently, as shown in FIG. 2B, a gate insulating film 17 is formed on the wall surface of the trench 16 by a CVD method or a PVD method. In this process, the gate insulating film 17 is formed also on the first surface 10a of the semiconductor substrate 10. In the present embodiment, thereafter, a heat treatment is performed in an oxygen and nitrogen (NO) atmosphere, so that a nitrogen termination process to terminate dangling bonds of the semiconductor substrate 10 at the interface with the gate insulating film 17 with nitrogen is performed to thereby form a termination structure. In other words, the termination structure is formed by terminating the dangling bonds of the base layer 14 at the interface with the gate insulating film 17 with nitrogen.

Next, as shown in FIG. 2C, doped polysilicon is arranged to fill the trench 16 by a CVD method or the like, so that a gate electrode 18 is formed in the trench 16. In addition, the doped polysilicon formed on the first surface 10a of the semiconductor substrate 10 is patterned so as to form a gate wiring connected to the gate electrode 18 in a cross-section different from that shown in FIG. 2C, while removing an excess of the doped polysilicon.

Subsequently, as shown in FIG. 2D, a lower insulating film 21 as a deposited film is formed by a CVD method, a PVD method or the like so as to cover the opening of the trench 16. At this time, since the lower insulating film 21 is formed by the CVD method, the PVD method or the like, it is less likely that the nitrogen in the termination structure will be replaced with oxygen.

Next, as shown in FIG. 2E, an upper insulating film 22 is formed by a CVD method or the like.

Thereafter, as shown in FIG. 2F, dry etching is performed using a mask (not shown) so as to simultaneously pattern the gate insulating film 17, the lower insulating film 21 and the upper insulating film 22, so that the base layer 14 and the source region 15 are exposed. Specifically, the gate insulating film 17, the lower insulating film 21, and the upper insulating film 22 are simultaneously patterned so as to form an interlayer insulating film 20 formed with a contact hole 23. At this time, as described above, the interlayer insulating film 20, which includes the lower insulating film 21 and the upper insulating film 22, has the shape protruding outward from the opening of the trench 16, as the planar shape. Thereafter, a heat treatment is performed to round the wall surface of the upper insulating film 22. In the heat treatment, there is a possibility that nitrogen in the termination structure will be replaced with oxygen. In the present embodiment, however, the interlayer insulating film 20 (i.e., the lower insulating film 21) has the shape protruding outward from the opening of the trench 16 as the planar shape. Therefore, oxygen is less likely to reach the interface between the gate insulating film 17 and the semiconductor substrate 10 during the heat treatment, and thus the replacement of nitrogen with oxygen can be suppressed. The processes after the nitrogen termination process may be performed at a temperature lower than the temperature of the nitrogen termination process by 50 degrees Celsius (° C.) or more.

Thereafter, although not particularly shown, an upper electrode 31 is formed on the first surface 10a side of the semiconductor substrate 10, and a lower electrode 32 is formed on the second surface 10b side of the semiconductor substrate 10. In this way, the SiC semiconductor device described above can be produced.

According to the present embodiment described above, the lower insulating film 21 of the interlayer insulating film 20 is provided by the deposited film. Therefore, as compared with a case where the lower insulating film 21 is provided by an oxide film or the like formed by oxidizing, nitrogen in the termination structure is less likely to be replaced with oxygen. As such, it is possible to suppress the occurrence of variation in threshold voltage.
(1) In the present embodiment, the interlayer insulating film 20 (i.e., the lower insulating film 21) has the shape protruding outward from the opening of the trench 16 in the planar direction. Therefore, in the case where an oxidation process or the like is performed after the lower insulating film 21 is formed, oxygen is less likely to reach the interface between the gate insulating film 17 and the semiconductor substrate 10, as compared with the case where the lower insulating film 21 is disposed only in the opening of the trench 16 in the planar direction. Therefore, it is possible to further suppress the replacement of nitrogen in the termination structure with oxygen. Since the lower insulating film 21 can restrict nitrogen in the termination structure from being replaced with oxygen, it is possible to perform the oxidation process after the lower insulating film 21 is formed. As such, the degree of freedom of the manufacturing process can be improved.
(2) In the present embodiment, the gate insulating film 17 is provided by the deposited film. Thus, the gate insulating film 17 is formed so that the thickness of the portion that is in contact with the source region 15 is 1.3 times or less the thickness of the portion that is in contact with the base layer 14. Therefore, for example, as compared with a case where the gate insulating film 17 is formed by the thermal oxidation, it is possible to suppress the variation in a thickness ratio of the gate insulating film 17. That is, the variation in the thickness of the gate insulating film 17 being in contact with the source region 15 can be suppressed. As such, it is possible to further suppress the variation in the threshold voltage. In addition, since the lower insulating film 21 is arranged in such a manner as described above, even when an oxidation process is performed after the lower insulating film 21 is formed, it is possible to suppress the gate insulating film 17 from becoming thick. Thus, it is possible to further suppress the variation in the threshold voltage.

### Second Embodiment

A second embodiment will be described hereinafter. The second embodiment has a temperature sensing section and an outer peripheral section, with respect to the SiC semiconductor device of the first embodiment. Other configurations of the second embodiment are similar to those of the first embodiment, and thus the descriptions thereof are not repeated.

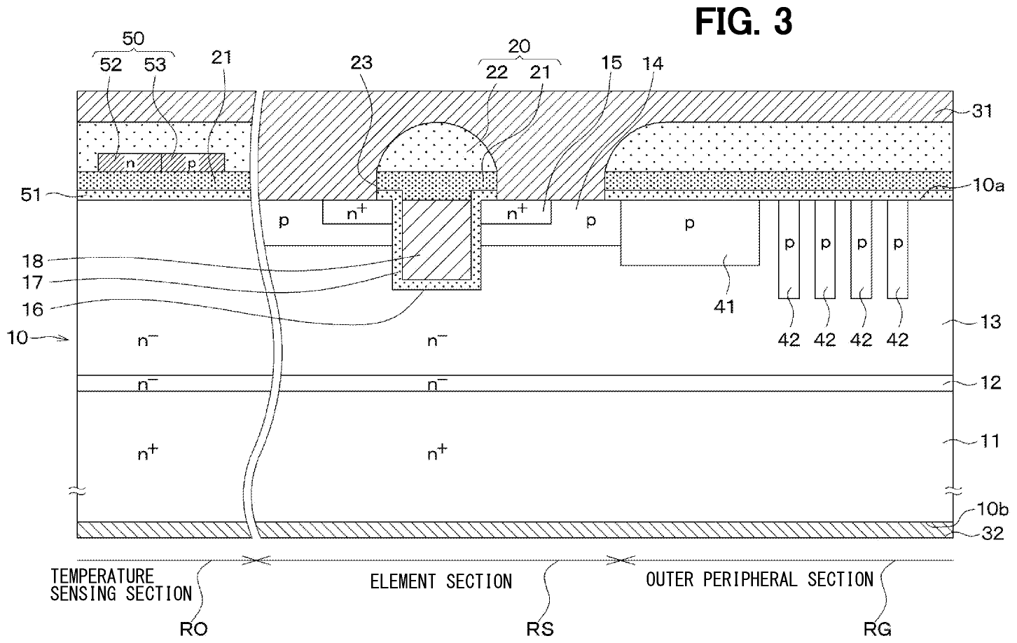

As shown in FIG. 3, the SiC semiconductor device of the present embodiment includes an element section RS, an outer peripheral section RG, and a temperature sensing section RO. The element section RS is provided with the MOSFET as described in the first embodiment.

The outer peripheral section RG is disposed around the element section RS. The outer peripheral section RG is provided with a p-type RESURF layer 41 on the first surface 10a side of the semiconductor substrate 10. The RESURF layer 41 is connected to the base layer 14. In the outer peripheral section RG, a p-type guard ring 42 is formed on the first surface 10a side of the semiconductor substrate 10. The p-type guard ring 42 is disposed opposite to the base layer 14 with respect to the RESURF layer 41 in the planar direction. The guard ring 42 is formed so as to generally surround the element section RS. For example, the guard ring 42 has a rectangular frame shape or an annular shape with rounded corners, as the planar shape.

The temperature sensing section RO is provided with a temperature sensing element 50. The temperature sensing element 50 of the present embodiment is configured by a pn diode in which a non-doped polysilicon is doped with an impurity. Specifically, in the temperature sensing section RO, an insulating film 51 and the lower insulating film 21 are disposed on the first surface 10a of the semiconductor substrate 10. The temperature sensing element 50 is provided by the pn diode in which an n-type region 52 doped with an n-type impurity and a p-type region 53 doped with a p-type impurity are disposed on the lower insulating film 21 so as to form a pn junction. Note that the insulating film 51 of the temperature sensing element 50 is provided by a portion that is formed on the first surface 10a of the semiconductor substrate 10 when the gate insulating film 17 is disposed.

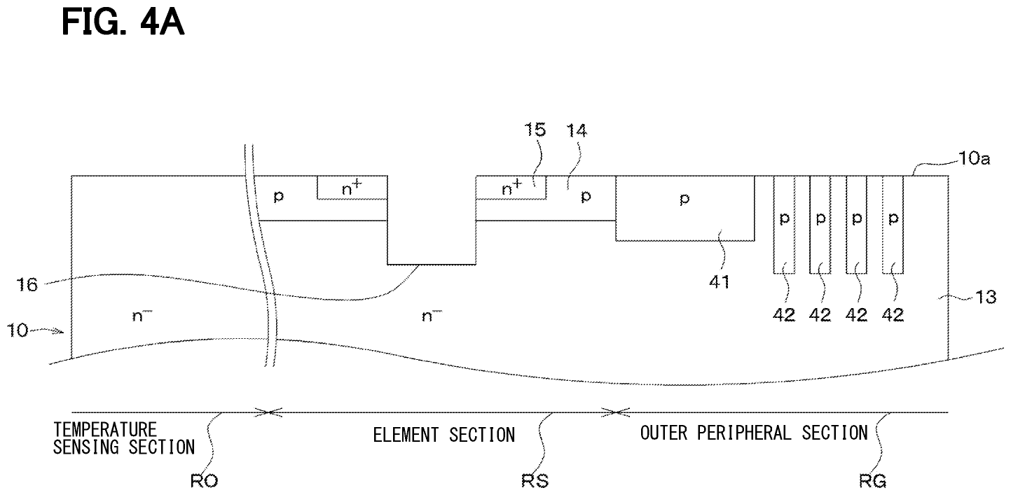

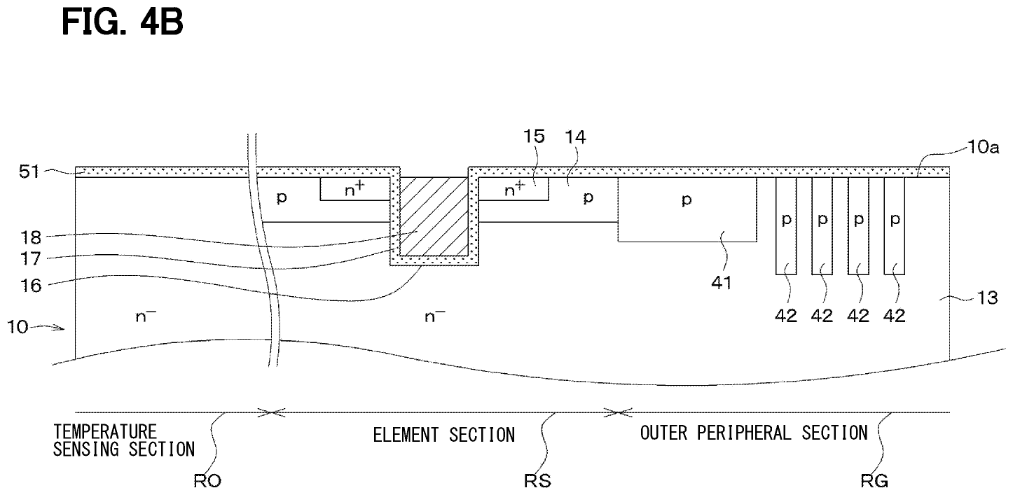

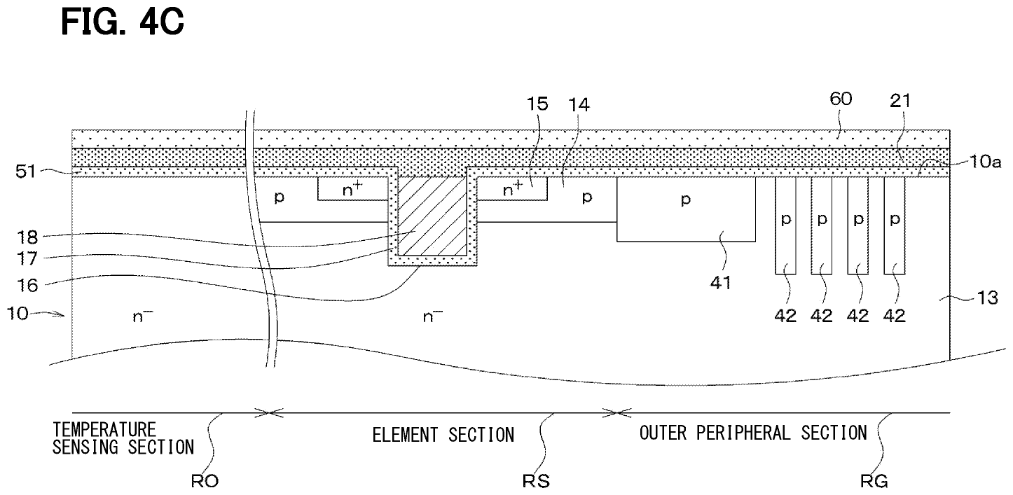

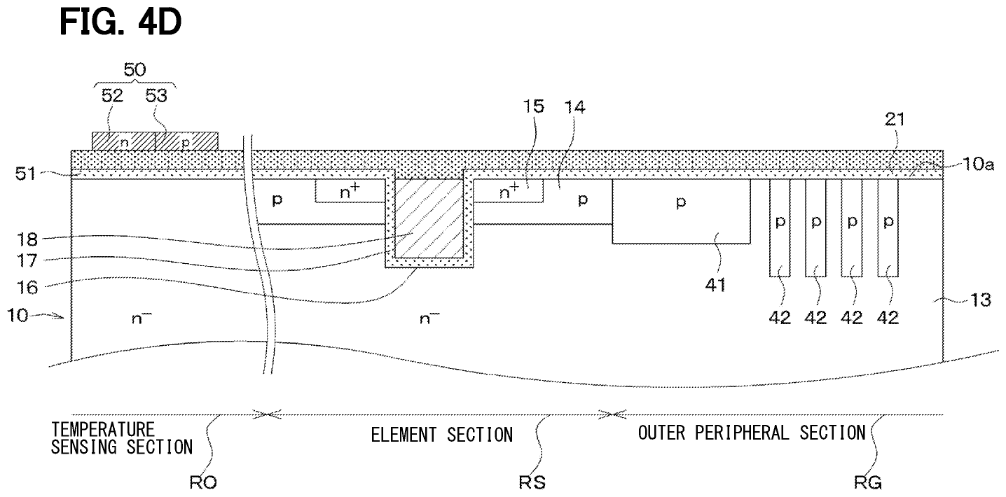

The SiC semiconductor device according to the present embodiment has the configurations described above. Next, a manufacturing method of such a SiC semiconductor device will be described with reference to FIGS. 4A to 4D.

First, as shown in FIG. 4A, a semiconductor substrate 10 formed with a base layer 14, a source region 15, a trench 16 and the like in an element section RS, and a RESURF layer 41, a guard ring 42 and the like in an outer peripheral section RG is prepared.

Subsequently, as shown in FIG. 4B, the same processes as in FIGS. 2B and 2C are performed. That is, a gate insulating film 17 is formed, and a termination process is performed. Thereafter, a gate electrode 18 is formed. In the present embodiment, an insulating film 51 is provided by the gate insulating film 17 formed in the temperature sensing section RO.

Next, as shown in FIG. 4C, the same process as in FIG. 2D is performed to arrange a lower insulating film 21. Then, a non-doped polysilicon 60 is arranged on the lower insulating film 21.

Subsequently, a mask (not shown) is arranged. As shown in FIG. 4D, to the non-doped polysilicon 60 arranged in the temperature sensing section RO, an n-type impurity is ion-implanted to form an n-type region 52, and a p-type impurity is ion-implanted to form a p-type region 53. Note that, before the ion implantations of the p-type impurity and the n-type impurity, a surface layer portion of the non-doped polysilicon 60 on the side opposite to the semiconductor substrate 10 may be oxidized in order to improve the crystallinity of the non-doped polysilicon 60. Note that also in this oxidation process, since the lower insulating film 21 is disposed on the gate electrode 18, nitrogen in the termination structure is less likely to be replaced with oxygen.

Next, a mask (not shown) is disposed, and the non-doped polysilicon 60 is patterned so that the temperature sensing element 50 including the n-type region 52 and the p-type region 53 is formed in the temperature sensing section RO. In the element section RS and the outer peripheral section RG, the non-doped polysilicon 60 is removed. At this time, since the lower insulating film 21 can be used as an etching stopper, patterning of the non-doped polysilicon can be easily performed.

Thereafter, although not particularly illustrated, the same processes as those in FIG. 2E and the subsequent figures are performed. That is, the upper insulating film 22 is arranged, and the gate insulating film 17, the lower insulating film 21, and the upper insulating film 22 are patterned to form the contact hole 23, thereby to expose the base layer 14 and the source region 15 in the element section RS. Thereafter, the upper electrode 31, the lower electrode 32, and the like are formed. In this way, the SiC semiconductor device shown in FIG. 3 is manufactured.

According to the present embodiment described above, since the lower insulating film 21 of the interlayer insulating film 20 is provided by the deposited film, it is possible to achieve the similar effects to those of the first embodiment.
(1) In the present embodiment, the lower insulating film 21 can be used as an etching stopper when the non-doped polysilicon 60 is removed. Therefore, the patterning of the non-doped polysilicon 60 can be facilitated.

### Modification of Second Embodiment

A modification of the second embodiment will be described. In the second embodiment described above, the non-doped polysilicon 60 may be patterned so that the lower insulating film 21 in the element section RS is configured to include the non-doped polysilicon 60. That is, the lower insulating film 21 may be formed by a stack of an oxide film and the non-doped polysilicon 60, for example. However, there is a possibility that the non-doped polysilicon 60 will react with the upper electrode 31 to form a metal silicide. Therefore, in the case where the temperature sensing element 50 is configured as in the second embodiment described above, it is preferable to remove the non-doped polysilicon 60 in the element section RS.

Further, in the process shown in FIG. 4D of the second embodiment, in the case where the surface layer portion of the non-doped polysilicon 60 on the side opposite to the semiconductor substrate 10 is oxidized in order to improve the crystallinity of the non-doped polysilicon 60, a process of removing only the oxidized portion may be performed.

### Other Embodiments

Although the present disclosure has been described with reference to embodiments, it is understood that the present disclosure is not limited to such embodiments or structures. The present disclosure encompasses various modifications and variation within the scope of equivalents. In addition, various combinations and forms, and other combinations and forms including only one element, more or less than one element are also within the scope and spirit of the present disclosure.

For example, in each of the embodiments described above, the interlayer insulating film 20 exemplarily includes the lower insulating film 21 and the upper insulating film 22. However, the interlayer insulating film 20 may not include the upper insulating film 22.

In each of the embodiments described above, it is exemplified that the upper insulating film 22 is also provided by the deposited film formed by a CVD method. However, the upper insulating film 22 may be a film formed by another method.

Furthermore, in each of the embodiments described above, the interlayer insulating film 20 may be formed so as to be positioned in the opening of the trench 16 in the plan view.

In each of the embodiments described above, the MOSFET having the trench gate structure of the n-channel type in which the first conductivity type is an n-type and the second conductivity type is a p-type is exemplified. However, the SiC semiconductor device may be provided with a MOSFET having a trench gate structure of a p-channel type in which the conductivity type of each component is inverted with respect to the n-channel type, for example. Further, the SiC semiconductor device may have a configuration in which an IGBT having a similar structure is formed in addition to the MOSFET. The IGBT has a similar configuration to the MOSFET described in each of the embodiments described above, except that the n⁺-type substrate 11 is changed to a p⁺-type collector layer.

What is claimed is:

1. A silicon carbide semiconductor device comprising:
a semiconductor substrate that includes a substrate made of silicon carbide of a first or second conductivity type, a drift layer of the first conductivity type disposed on the substrate and having an impurity concentration lower than that of the substrate, a base layer of the second conductivity type disposed on the drift layer, and an impurity region of the first conductivity type disposed in a surface layer portion of the base layer;
a trench gate structure that includes a gate insulating film disposed on a wall surface of a trench penetrating the impurity region and the base layer and reaching the drift layer, and a gate electrode disposed on the gate insulating film;
a first electrode that is electrically connected to the impurity region and the base layer;
a second electrode that is electrically connected to the substrate; and
an interlayer insulating film that is disposed between the gate electrode and the first electrode to insulate the gate electrode and the first electrode from each other, wherein
a portion of the semiconductor substrate adjoining the trench has a termination structure in which dangling bonds are terminated with at least one selected from a group consisting of nitrogen, hydrogen, and phosphorus,
the interlayer insulating film includes a contact insulating film that is in contact with the gate electrode, and
the contact insulating film is provided by a deposited film.

2. The silicon carbide semiconductor device according to claim 1, wherein
the interlayer insulating film has a shape protruding outward from an opening of the trench in a planar direction of the semiconductor substrate.

3. A manufacturing method of a silicon carbide semiconductor device, the semiconductor device including:
a semiconductor substrate that includes a substrate made of silicon carbide of a first or second conductivity type, a drift layer of the first conductivity type disposed on the substrate and having an impurity concentration lower than that of the substrate, a base layer of the second conductivity type disposed on the drift layer, and an impurity region of the first conductivity type disposed in a surface layer portion of the base layer;
a trench gate structure that includes a gate insulating film disposed on a wall surface of a trench penetrating the impurity region and the base layer and reaching the drift layer, and a gate electrode disposed on the gate insulating film;
a first electrode that is electrically connected to the impurity region and the base layer;
a second electrode that is electrically connected to the substrate; and
an interlayer insulating film disposed between the gate electrode and the first electrode to insulate the gate electrode and the first electrode from each other, wherein
a portion of the semiconductor substrate adjoining the trench has a termination structure in which dangling bonds are terminated with at least one selected from a group consisting of nitrogen, hydrogen, and phosphorus,
the interlayer insulating film includes a contact insulating film that is in contact with the gate electrode, and
the contact insulating film is provided by a deposited film,
the manufacturing method of the silicon carbide semiconductor device, comprising:
preparing the semiconductor substrate formed with the base layer, the impurity region, and the trench;
arranging the gate insulating film on the wall surface of the trench;
forming the termination structure by bonding the at least one selected from the group consisting of nitrogen, hydrogen, and phosphorus to the dangling bonds in the portion of the semiconductor substrate adjoining the trench;
arranging the gate electrode on the gate insulating film;
arranging the interlayer insulating film in a region including a portion above the gate electrode; and
patterning the interlayer insulating film so as to expose the impurity region and the base layer, wherein
the arranging of the interlayer insulating film includes forming the contact insulating film by a deposition method.

4. The manufacturing method according to claim 3, wherein
in the patterning of the interlayer insulating film, the interlayer insulating film is patterned so that the interlayer insulating film has a shape protruding outward from an opening of the trench in a planar direction of the semiconductor substrate.

5. The manufacturing method according to claim 3, wherein
in the preparing of the semiconductor substrate, the semiconductor substrate including an element section and a temperature sensing section is prepared, and
the forming of the trench includes forming a trench in the element section,
the method further comprising:
after the arranging of the contact insulating film, arranging a non-doped polysilicon;
performing an ion-implantation to the non-doped polysilicon arranged in the temperature sensing section so as to form a temperature sensing element having a first conductivity type region and a second conductivity type region connected to each other; and
removing the non-doped polysilicon arranged in the element section by using the contact insulating film as an etching stopper.
